(19) United States
(12) Patent Application Publication
(10) Pub. No.: US 2022/0173066 A1
(43) Pub. Date: Jun. 2, 2022

(54) FLEXIBLE HYBRID ELECTRONICS MANUFACTURING METHOD

(71) Applicant: Flex Ltd., Singapore (SG)

(72) Inventor: Weifeng Liu, Dublin, CA (US)

(73) Assignee: Flex Ltd., Singapore (SG)

(21) Appl. No.: 17/540,561

(22) Filed: Dec. 2, 2021

Related U.S. Application Data
(60) Provisional application No. 63/120,590, filed on Dec. 2, 2020.

(51) Int. Cl. H01L 23/00; H01L 23/498; H01L 23/544

(52) U.S. Cl. CPC H01L 24/19; H01L 23/4985; H01L 2223/54486; H01L 23/544; H01L 2224/211; H01L 24/20

(57) ABSTRACT

Embodiments of the present disclosure are directed to using direct ink printing on chips or interposer pads to replace the other die bonding process, e.g., conductive adhesive, Anisotropic Conductive Film (ACF), solder, etc. Direct printing on contact pads of chips and/or interposers to replace using ACF bonding provides simplicity of manufacturing process, reduced cost by eliminating ACF, reduced interconnect resistance by eliminating ACF interface, and increased reliability by eliminating ACF bonding instability. Direct printing according to embodiments of the present disclosure can make complex design patterns with fine pitch capability (sub 10 micron is feasible by using aerosol jet printing, 30 microns or above for screen printing). Such direct printing can also enable roll to roll printing process for high volume production.

### CROSS REFERENCE TO RELATED APPLICATION

The present application claims the benefits of and priority, under 35 U.S.C. § 119(e), to U.S. Provisional Application No. 63/120,590 filed Dec. 2, 2020 by Liu and entitled “Flexible Hybrid Electronics Manufacturing Method” of which the entire disclosure is incorporated herein by reference for all purposes.

### FIELD OF THE DISCLOSURE

Embodiments of the present disclosure relate generally to methods and systems for electronics manufacturing and more particularly to making interconnections between semiconductors and/or interposers and printed ink traces for Flexible Hybrid Electronic (FHE) application.

### BACKGROUND

Typically, chips and/or interposers are attached on printing ink through an Anisotropic Conductive Film (ACF) bonding. This is an extra process of bonding and curing. The high temperature and high pressure of this process may cause excess damage to substrates and thin chips. This can be especially problematic in Flexible Hybrid Electronic (FHE) applications. ACF bonding also requires expensive bonding machines, many of which have a limited pitch capability. This is an extra cost and fine pitch ACF machines are typically very expensive. Hence, there is a need for improved methods and systems for making interconnections between semiconductors and/or interposers and printed ink traces for FHE application.

### BRIEF DESCRIPTION OF THE DRAWINGS

FIGS. 1A-1E are a sequence of block diagrams illustrating a cross-sectional side view of a Flexible Hybrid Electronic (FHE) device at various stages of a manufacturing process according to one embodiment the present disclosure.

FIG. 2 is a flowchart illustrating an exemplary process for manufacturing an FHE device according to the embodiment of the present disclosure illustrated in FIGS. 1A-1E.

FIGS. 3A-3F are a sequence of block diagrams illustrating a cross-sectional side view of an FHE device at various stages of a manufacturing process according to another embodiment the present disclosure.

FIG. 4 is a flowchart illustrating an exemplary process for manufacturing an FHE device according to the embodiment of the present disclosure illustrated in FIGS. 3A-3F.

FIGS. 5A-5G are a sequence of block diagrams illustrating a cross-sectional side view of an FHE device at various stages of a manufacturing process according to yet another embodiment the present disclosure.

FIG. 6 is a flowchart illustrating an exemplary process for manufacturing an FHE device according to the embodiment of the present disclosure illustrated in FIGS. 5A-5G.

FIGS. 7A-7H are a sequence of block diagrams illustrating a cross-sectional side view of an FHE device at various stages of a manufacturing process according to still another embodiment the present disclosure.

FIG. 8 is a flowchart illustrating an exemplary process for manufacturing an FHE device according to the embodiment of the present disclosure illustrated in FIGS. 7A-7H.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the second reference label.

### DETAILED DESCRIPTION

In the following description, for the purposes of explanation, numerous specific details are set forth in order to provide a thorough understanding of various embodiments disclosed herein. It will be apparent, however, to one skilled in the art that various embodiments of the present disclosure may be practiced without some of these specific details. The ensuing description provides exemplary embodiments only and is not intended to limit the scope or applicability of the disclosure. Furthermore, to avoid unnecessarily obscuring the present disclosure, the preceding description omits a number of known structures and devices. This omission is not to be construed as a limitation of the scopes of the claims. Rather, the ensuing description of the exemplary embodiments will provide those skilled in the art with an enabling description for implementing an exemplary embodiment. It should however be appreciated that the present disclosure may be practiced in a variety of ways beyond the specific detail set forth herein.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted that the terms “comprising,” “including,” and “having” can be used interchangeably.

The term “automatic” and variations thereof, as used herein, refers to any process or operation done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material.”

It shall be understood that the term “means” as used herein shall be given its broadest possible interpretation in accordance with 35 U.S.C., Section 112, Paragraph 6. Accordingly, a claim incorporating the term “means” shall cover all structures, materials, or acts set forth herein, and all of the equivalents thereof. Further, the structures, materials or acts and the equivalents thereof shall include all those described in the summary of the disclosure, brief description of the drawings, detailed description, abstract, and claims themselves.

Although the present disclosure describes components and functions implemented in the aspects, embodiments, and/or configurations with reference to particular standards and protocols, the aspects, embodiments, and/or configurations are not limited to such standards and protocols. Other similar standards and protocols not mentioned herein are in existence and are considered to be included in the present disclosure. Moreover, the standards and protocols mentioned herein and other similar standards and protocols not mentioned herein are periodically superseded by faster or more effective equivalents having essentially the same functions. Such replacement standards and protocols having the same functions are considered equivalents included in the present disclosure.

Various additional details of embodiments of the present disclosure will be described below with reference to the figures. While the flowcharts will be discussed and illustrated in relation to a particular sequence of events, it should be appreciated that changes, additions, and omissions to this sequence can occur without materially affecting the operation of the disclosed embodiments, configuration, and aspects.

Embodiments of the present disclosure are directed to using direct ink printing on chips or interposer pads to replace the other die bonding process, e.g., conductive adhesive, Anisotropic Conductive Film (ACF), solder, etc. Direct printing on contact pads of chips and/or interposers to replace using ACF bonding provides simplicity of manufacturing process, reduced cost by eliminating ACF, reduced interconnect resistance by eliminating ACF interface, and increased reliability by eliminating ACF bonding instability. Direct printing according to embodiments of the present disclosure can make complex design patterns with fine pitch capability (sub 10 micron is feasible by using aerosol jet printing, 30 microns or above for screen printing). Such direct printing can also enable roll to roll printing process for high volume production.

A variety of materials can be used in various embodiments of the present disclosure. For example, a conductive ink as described herein can comprise silver, copper, nickel, or their alloys or mixtures. A substrate or ink printing/encapsulation substrate as used herein can comprise Thermoplastic polyurethane (TPU), polydimethylsiloxane (PDMS), polytetrafluoroethylene (PTFE), or any other polymer that can be laminated under heat and pressure. The substrate films can be many varieties with different thickness and durometer grade. A chip or interposer as described herein can comprise surface mount metal pads of gold, silver, tin coated copper pads with nickel underplate, etc.

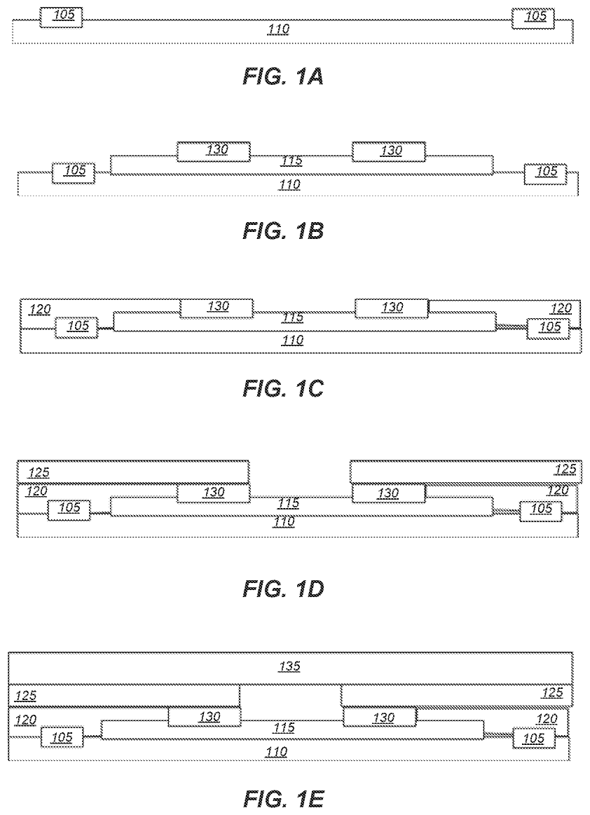

FIGS. 1A-1E are a sequence of block diagrams illustrating a cross-sectional side view of a Flexible Hybrid Electronic (FHE) device at various stages of a manufacturing process according to one embodiment the present disclosure. More specifically, as illustrated by FIG. 1A, fiducials 105 can be printed on a carrier substrate 110. This can be done with conductive ink or nonconductive ink. As illustrated in FIG. 1B, a chip or interposer 115 can be aligned with the fiducials 105 and attached on the substrate 110. As illustrated in FIG. 1C, a window can be cut in the ink printing substrate 120 which can in turn be laminated to the carrier substrate 110 and chip or interposer 115 though heat and/or pressure. As illustrated in FIG. 1D, ink 125 can be printed on the ink printing substrate 120 and contact pads 130 of the chip or interposer 115 and then cured at high temperature. As illustrated in FIG. 1E, heat and pressure can be applied to laminate an encapsulation layer 135 on top of the whole stack up. The lamination schedule can vary, such as 180 C for 20 seconds or 120 C for 1 minute.

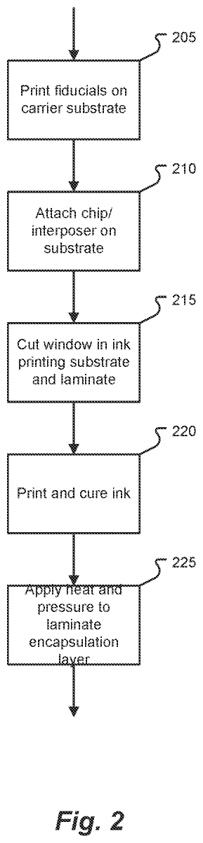

FIG. 2 is a flowchart illustrating an exemplary process for manufacturing an FHE device according to the embodiment of the present disclosure illustrated in FIGS. 1A-1E. As illustrated in this example, assembling a FHE device can comprise printing 205 a plurality of fiducials on a carrier substrate of the FHE device and attaching 210 a chip or chip interposer to the carrier substrate of the FHE device. The chip or chip interposer can be aligned with the plurality of fiducials. In some cases, a window can be cut 215 into the ink printing substrate laminated over the chip or chip interposer. One or more conductive traces can be printed 220 onto the ink printing substrate and contacts pads of the chip or chip interposer using a conductive ink. After printing the one or more conductive traces onto the ink printing substrate, the one or more conductive traces can be cured. For example, curing the one or more conductive traces can comprise applying 120 degrees Celsius for 10 minutes. Heat and pressure can be applied 225 to laminate an encapsulation layer disposed over the FHE device to the one or more conductive traces, ink printing substrate, chip or chip interposer, and carrier substrate. For example, applying heat and pressure to laminate the encapsulation layer disposed over the FHE device to the one or more conductive traces, ink printing substrate, chip or chip interposer, and carrier substrate can comprise applying 180 degrees Celsius for 20 seconds or 120 degrees Celsius for 1 minute.

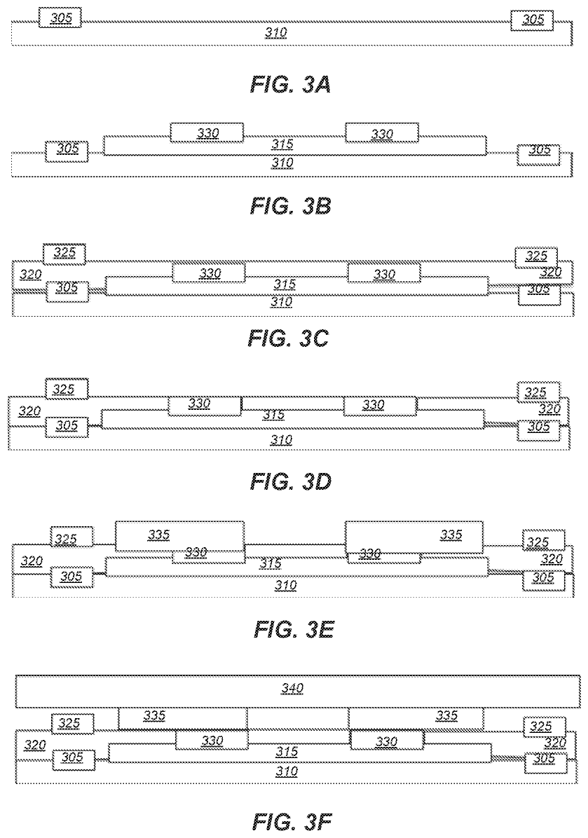

FIGS. 3A-3F are a sequence of block diagrams illustrating a cross-sectional side view of an FHE device at various stages of a manufacturing process according to another embodiment the present disclosure. More specifically, as illustrated by FIG. 3A, fiducials 305 can be printed on a carrier substrate 310. This can be done with conductive ink or nonconductive ink. As illustrated in FIG. 3B, a chip or interposer 315 can be aligned with the fiducials 305 and attached on the substrate 310. As illustrated in FIG. 3C, the ink printing substrate 320 can be laminated to the carrier substrate 310 and chip or interposer 315 though heat and/or pressure, e.g., at 80 C for 20 seconds. The ink printing substrate 320 may also include fiducials 325. As illustrated in FIG. 3D, a laser or other device may be used to strip the ink printing substrate 320 to expose the contact pads 330 of the chip or interposer 315. As illustrated in FIG. 3E, ink 335 can be printed on the ink printing substrate 320 and contact pads 330 of the chip or interposer 315 and then cured at high temperature, e.g., 120 C for 10 minutes. As illustrated in FIG. 3F, heat and pressure can be applied to laminate an encapsulation layer 340 on top of the whole stack up. The lamination schedule can vary, such as 180 C for 20 seconds or 120 C for 1 minute.

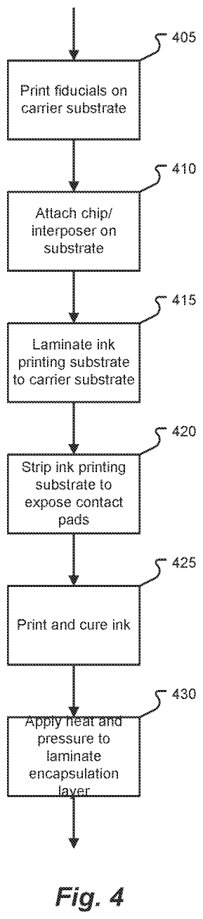

FIG. 4 is a flowchart illustrating an exemplary process for manufacturing an FHE device according to the embodiment of the present disclosure illustrated in FIGS. 3A-3F. As illustrated in this example, assembling a FHE device can comprise printing 405 a plurality of fiducials on a carrier substrate of the FHE device and attaching 410 a chip or chip interposer to the carrier substrate of the FHE device. The chip or chip interposer can be aligned with the plurality of fiducials. An ink printing substrate can be laminated 415 onto the chip or chip interposer and/or carrier substrate, for example, by applying 80 degrees Celsius for 20 seconds. After laminating the ink printing substrate onto the chip or chip interposer the ink printing substrate can be stripped 420 from one or more contact pads of the chip or chip interposer to expose the contact pads of the ship or chip interposer, e.g., using a laser. One or more conductive traces can be printed 425 onto the ink printing substrate and contacts pads of the chip or chip interposer using a conductive ink. After printing the one or more conductive traces onto the ink printing substrate, the one or more conductive traces can be cured. For example, curing the one or more conductive traces can comprise applying 120 degrees Celsius for 10 minutes. Heat and pressure can be applied 430 to laminate an encapsulation layer disposed over the FHE device to the one or more conductive traces, ink printing substrate, chip or chip interposer, and carrier substrate. For example, applying heat and pressure to laminate the encapsulation layer disposed over the FHE device to the one or more conductive traces, ink printing substrate, chip or chip interposer, and carrier substrate can comprise applying 180 degrees Celsius for 20 seconds or 120 degrees Celsius for 1 minute.

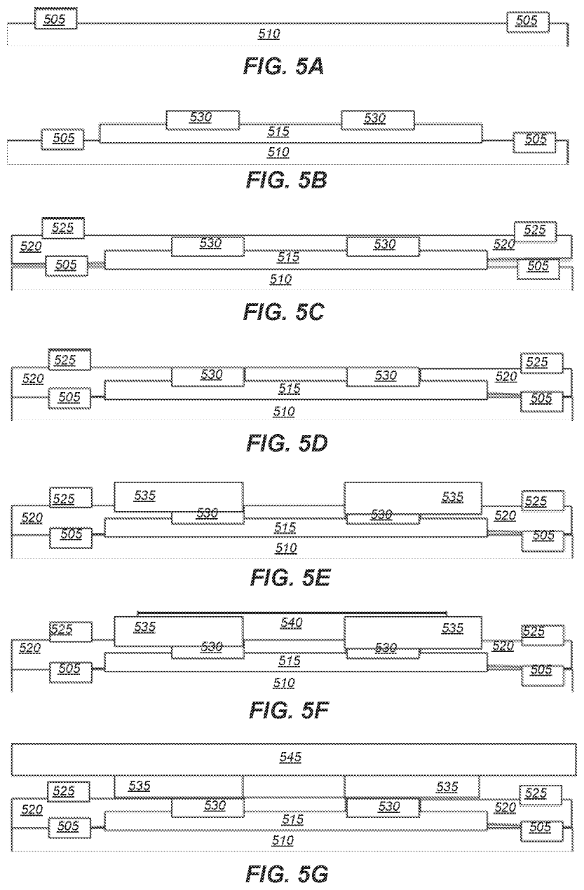

FIGS. 5A-5G are a sequence of block diagrams illustrating a cross-sectional side view of an FHE device at various stages of a manufacturing process according to yet another embodiment the present disclosure. More specifically, as illustrated by FIG. 5A, fiducials 505 can be printed on a carrier substrate 510. This can be done with conductive ink or nonconductive ink. As illustrated in FIG. 5B, a chip or interposer 515 can be aligned with the fiducials 505 and attached on the substrate 510. As illustrated in FIG. 5C, the ink printing substrate 520 can be laminated to the carrier substrate 510 and chip or interposer 515 though heat and/or pressure, e.g., at 80 C for 20 seconds. The ink printing substrate 520 may also include fiducials 525. As illustrated in FIG. 5D, a laser or other device may be used to strip the ink printing substrate 520 to expose the contact pads 530 of the chip or interposer 515. As illustrated in FIG. 5E, ink 535 can be printed on the ink printing substrate 520 and contact pads 530 of the chip or interposer 515 and then cured at high temperature, e.g., at 120 C for 10 minutes. As illustrated in FIG. 5F, a more rigid, i.e., high modulus, film 540 can be laminated on top of the ink 535 to cover the ink-contact pads area to provide protection to the ink-pad interconnect. As illustrated in FIG. 5G, heat and pressure can be applied to laminate an encapsulation layer 545 on top of the whole stack up. The lamination schedule can vary, such as 180 C for 20 seconds or 120 C for 1 minute.

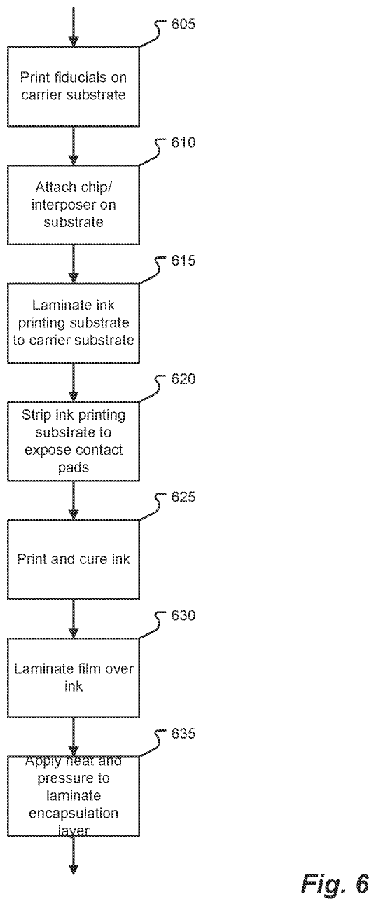

FIG. 6 is a flowchart illustrating an exemplary process for manufacturing an FHE device according to the embodiment of the present disclosure illustrated in FIGS. 5A-5G. As illustrated in this example, assembling a FHE device can comprise printing 605 a plurality of fiducials on a carrier substrate of the FHE device and attaching 610 a chip or chip interposer to the carrier substrate of the FHE device. The chip or chip interposer can be aligned with the plurality of fiducials. An ink printing substrate can be laminated 615 onto the chip or chip interposer and/or carrier substrate, for example, by applying 80 degrees Celsius for 20 seconds. After laminating the ink printing substrate onto the chip or chip interposer the ink printing substrate can be stripped 620 from one or more contact pads of the chip or chip interposer to expose the contact pads of the ship or chip interposer, e.g., using a laser. One or more conductive traces can be printed 625 onto the ink printing substrate and contacts pads of the chip or chip interposer using a conductive ink. After printing the one or more conductive traces onto the ink printing substrate, the one or more conductive traces can be cured. For example, curing the one or more conductive traces can comprise applying 120 degrees Celsius for 10 minutes. After printing the one or more conductive traces onto the ink printing substrate a reinforcing film can be laminated 630 over and covering the one or more conductive traces and the contact pads of the chip or chip interposer. Heat and pressure can be applied 635 to laminate an encapsulation layer disposed over the FHE device to the one or more conductive traces, ink printing substrate, chip or chip interposer, and carrier substrate. For example, applying heat and pressure to laminate the encapsulation layer disposed over the FHE device to the one or more conductive traces, ink printing substrate, chip or chip interposer, and carrier substrate can comprise applying 180 degrees Celsius for 20 seconds or 120 degrees Celsius for 1 minute.

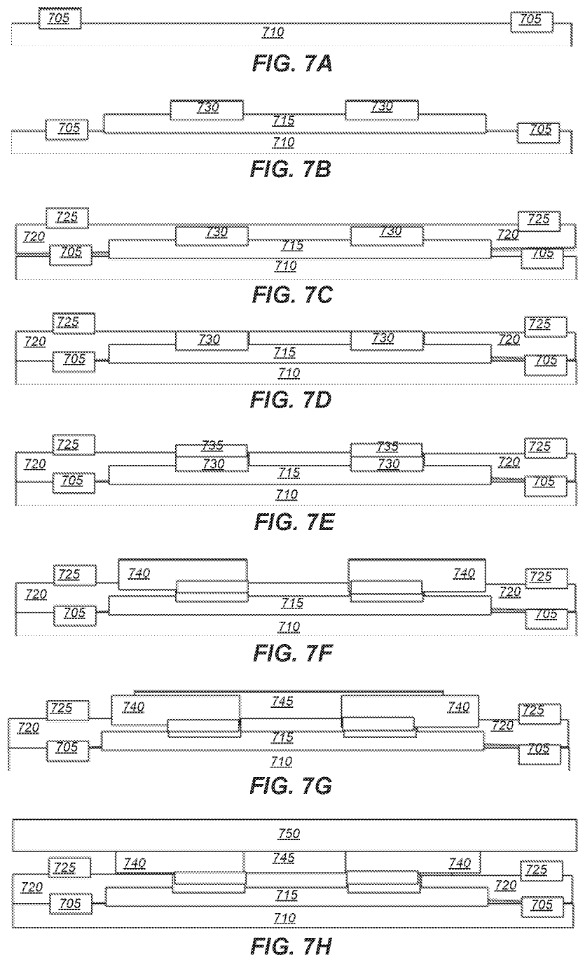

FIGS. 7A-7H are a sequence of block diagrams illustrating a cross-sectional side view of an FHE device at various stages of a manufacturing process according to still another embodiment the present disclosure. More specifically, as illustrated by FIG. 7A, fiducials 705 can be printed on a carrier substrate 710. This can be done with conductive ink or nonconductive ink. As illustrated in FIG. 7B, a chip or interposer 715 can be aligned with the fiducials 705 and attached on the substrate 710. As illustrated in FIG. 7C, the ink printing substrate 720 can be laminated to the carrier substrate 710 and chip or interposer 715 though heat and/or pressure, e.g., at 80 C for 20 seconds. In some cases, this substrate can come with adhesive layer for better bonding with the die/interposer and carrier substrate. As illustrated in FIG. 7D, a laser or other device may be used to strip the ink printing substrate 720 to expose the contact pads 730 of the chip or interposer 715. As illustrated in FIG. 7E, a conductive adhesive can be printed or dispensed and cured on the pads 735 to form the conductive bumps to be connected to the printed ink traces. As illustrated in FIG. 7F, ink 740 can be printed on the ink printing substrate 720 and contact pads 735 and then cured at high temperature, e.g., at 120 C for 10 minutes. As illustrated in FIG. 7G, a more rigid, i.e., high modulus, film 745 can be laminated on top of the ink 740 to cover the ink-contact pads 735 to provide protection to the ink-pad interconnect. As illustrated in FIG. 7H, heat and pressure can be applied to laminate an encapsulation layer 750 on top of the whole stack up. The lamination schedule can vary, such as 180 C for 20 seconds or 120 C for 1 minute.

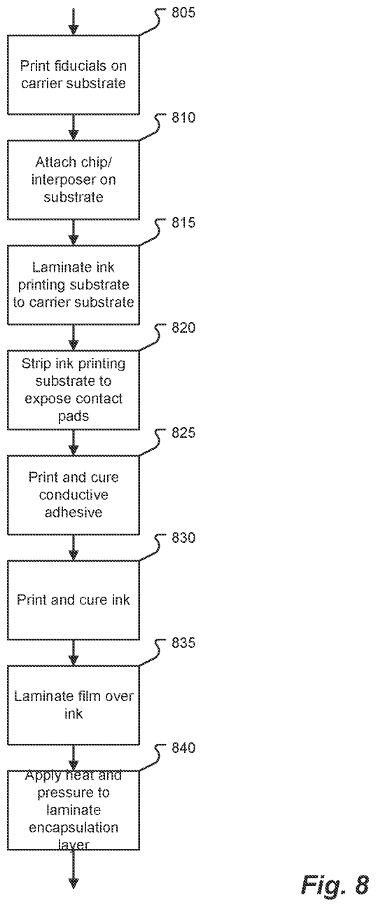

FIG. 8 is a flowchart illustrating an exemplary process for manufacturing an FHE device according to the embodiment of the present disclosure illustrated in FIGS. 7A-7H. As illustrated in this example, assembling a FHE device can comprise printing 805 a plurality of fiducials on a carrier substrate of the FHE device and attaching 810 a chip or chip interposer to the carrier substrate of the FHE device. The chip or chip interposer can be aligned with the plurality of fiducials. An ink printing substrate can be laminated 815 onto the chip or chip interposer and/or carrier substrate, for example, by applying 80 degrees Celsius for 20 seconds. In some cases, the ink printing substrate can comprise an adhesive layer. After laminating the ink printing substrate onto the chip or chip interposer the ink printing substrate can be stripped 820 from one or more contact pads of the chip or chip interposer to expose the contact pads of the ship or chip interposer, e.g., using a laser. One or more bumps of conductive adhesive can be printed 825 onto the conductive pads of the chip or chip interposer. One or more conductive traces can be printed 830 onto the ink printing substrate and contacts pads of the chip or chip interposer using a conductive ink. The one or more conductive traces can be connected with the one or more bumps of conductive adhesive. After printing the one or more conductive traces onto the ink printing substrate, the one or more conductive traces can be cured. For example, curing the one or more conductive traces can comprise applying 120 degrees Celsius for 10 minutes. After printing the one or more conductive traces onto the ink printing substrate a reinforcing film can be laminated 835 over and covering the one or more conductive traces and the contact pads of the chip or chip interposer. Heat and pressure can be applied 840 to laminate an encapsulation layer disposed over the FHE device to the one or more conductive traces, ink printing substrate, chip or chip interposer, and carrier substrate. For example, applying heat and pressure to laminate the encapsulation layer disposed over the FHE device to the one or more conductive traces, ink printing substrate, chip or chip interposer, and carrier substrate can comprise applying 180 degrees Celsius for 20 seconds or 120 degrees Celsius for 1 minute.

The present disclosure, in various aspects, embodiments, and/or configurations, includes components, methods, processes, systems, and/or apparatus substantially as depicted and described herein, including various aspects, embodiments, configurations embodiments, sub-combinations, and/or subsets thereof. Those of skill in the art will understand how to make and use the disclosed aspects, embodiments, and/or configurations after understanding the present disclosure. The present disclosure, in various aspects, embodiments, and/or configurations, includes providing devices and processes in the absence of items not depicted and/or described herein or in various aspects, embodiments, and/or configurations hereof, including in the absence of such items as may have been used in previous devices or processes, e.g., for improving performance, achieving ease and\or reducing cost of implementation.

The foregoing discussion has been presented for purposes of illustration and description. The foregoing is not intended to limit the disclosure to the form or forms disclosed herein. In the foregoing Detailed Description for example, various features of the disclosure are grouped together in one or more aspects, embodiments, and/or configurations for the purpose of streamlining the disclosure. The features of the aspects, embodiments, and/or configurations of the disclosure may be combined in alternate aspects, embodiments, and/or configurations other than those discussed above. This method of disclosure is not to be interpreted as reflecting an intention that the claims require more features than are expressly recited in each claim. Rather, as the following claims reflect, inventive aspects lie in less than all features of a single foregoing disclosed aspect, embodiment, and/or configuration. Thus, the following claims are hereby incorporated into this Detailed Description, with each claim standing on its own as a separate preferred embodiment of the disclosure.

Moreover, though the description has included description of one or more aspects, embodiments, and/or configurations and certain variations and modifications, other variations, combinations, and modifications are within the scope of the disclosure, e.g., as may be within the skill and knowledge of those in the art, after understanding the present disclosure. It is intended to obtain rights which include alternative aspects, embodiments, and/or configurations to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

What is claimed is:

1. A method for assembling a Flexible Hybrid Electronic (FHE) device, the method comprising:
printing a plurality of fiducials on a carrier substrate of the FHE device;
attaching a chip or chip interposer to the carrier substrate of the FHE device, the chip or chip interposer aligned with the plurality of fiducials;
laminating an ink printing substrate onto the chip or chip interposer;
printing one or more conductive traces onto the ink printing substrate and contacts pads of the chip or chip interposer; and
applying heat and pressure to laminate an encapsulation layer disposed over the FHE device to the one or more conductive traces, ink printing substrate, chip or chip interposer, and carrier substrate.

2. The method of claim 1, further comprising, prior to laminating the ink printing substrate onto the chip or chip interposer, cutting a window into the ink printing substrate over the chip or chip interposer.

3. The method of claim 1, wherein applying heat and pressure to laminate the encapsulation layer disposed over the FHE device to the one or more conductive traces, ink printing substrate, chip or chip interposer, and carrier substrate comprises applying 180 degrees Celsius for 20 seconds.

4. The method of claim 1, wherein applying heat and pressure to laminate the encapsulation layer disposed over the FHE device to the one or more conductive traces, ink printing substrate, chip or chip interposer, and carrier substrate comprises applying 120 degrees Celsius for 1 minute.

5. The method of claim 1, wherein laminating the ink printing substrate onto the chip or chip interposer comprises applying 80 degrees Celsius for 20 seconds.

6. The method of claim 1, further comprising, after laminating the ink printing substrate onto the chip or chip interposer and prior to printing the one or more conductive traces onto the ink printing substrate, stripping the ink printing substrate from one or more contact pads of the chip or chip interposer to expose the contact pads of the ship or chip interposer.

7. The method of claim 1, further comprising after printing the one or more conductive traces onto the ink printing substrate, curing the one or more conductive traces.

8. The method of claim 7, wherein curing the one or more conductive traces comprises applying 120 degrees Celsius for 10 minutes.

9. The method of claim 1, further comprising after printing the one or more conductive traces onto the ink printing substrate and before applying heat and pressure to laminate the encapsulation layer disposed over the FHE device to the one or more conductive traces, ink printing substrate, chip or chip interposer, and carrier substrate, laminating a reinforcing film covering the one or more conductive traces and the contact pads of the chip or chip interposer.

10. The method of claim 1, wherein the ink printing substrate comprises an adhesive layer.

11. The method of claim 1, further comprising printing one or more bumps of conductive adhesive onto the conductive pads of the chip or chip interposer, and wherein the one or more conductive traces are connected with the one or more bumps of conductive adhesive.

12. A Flexible Hybrid Electronic (FHE) device comprising:
a carrier substrate;
a plurality of fiducials printing onto the carrier substrate;
a chip or chip interposer attached to the carrier substrate, the chip or chip interposer aligned with the plurality of fiducials;
an ink printing substrate laminated onto the chip or chip interposer;
one or more conductive traces printed onto the ink printing substrate and contacts pads of the chip or chip interposer; and
an encapsulation layer disposed over and laminated onto the one or more conductive traces, ink printing substrate, chip or chip interposer, and carrier substrate.

13. The FHE device of claim 12, further comprising, a window cut into the ink printing substrate over the chip or chip interposer.

14. The FHE device of claim 12, wherein the ink printing substrate does not cover contact pads of the chip or chip interposer.

15. The FHE device of claim 12, further comprising a reinforcing film covering and laminated onto the one or more conductive traces and the contact pads of the chip or chip interposer.

16. The FHE device of claim 12, wherein the ink printing substrate comprises an adhesive layer.

17. The FHE device of claim 12, further comprising one or more bumps of conductive adhesive printed onto the conductive pads of the chip or chip interposer, and wherein the one or more conductive traces are connected with the one or more bumps of conductive adhesive.

18. The FHE device of claim 12, wherein the one or more conductive traces are printed conductive ink comprising silver, copper, nickel, or an alloy.

19. The FHE device of claim 12, wherein the carrier substrate, ink printing substrate, and encapsulation layer comprise one or more of Thermoplastic polyurethane (TPU), polydimethylsiloxane (PDMS), or polytetrafluoroethylene (PTFE).

20. The FHE device of claim 12, wherein the chip or chip interposer comprises surface mount metal pads of gold, silver, or tin coated copper pads with a nickel underplate.
